(19) United States
(12) Patent Application Publication
(10) Pub. No.: US 2004/0050586 A1
(43) Pub. Date: Mar. 18, 2004

(54) Circuit board where circuit terminals are interconnected and method of fabricating the same

(76) Inventor: Hyoung-ho Roh, Yongin-si (KR)

Correspondence Address: ST. ONGE STEWARD JOHNSTON & REENS, LLC, 986 BEDFORD STREET, STAMFORD, CT, 06905-5619, US

(21) Appl. No.: 10/458,400

(22) Filed: Jun. 10, 2003

(30) Foreign Application Priority Data
Jun. 10, 2002 (KR) 2002-32334

(51) Int. Cl. H05K 1/16; H05K 3/36

(52) U.S. Cl. 174/260; 29/830; 29/846; 29/847

(57) ABSTRACT

A circuit board includes a substrate having a top surface and a bottom surface and including circuit patterns disposed on the top and bottom surfaces thereof, the substrate defining a connection hole therein; an upper terminal electrically connected to a circuit pattern formed on the top surface of the substrate; a lower terminal electrically connected to a circuit pattern formed on the bottom surface of the substrate, the lower terminal being located opposite to the upper terminal; and wherein the upper terminal and the lower terminal are bonded inside the connection hole of the substrate for electrical connection there-between. A method of fabricating the circuit board is also disclosed.

### CROSS-REFERENCES TO RELATED APPLICATIONS

This application claims priority from Korean Patent Application No. 2002-32334, filed on Jun. 10, 2002, in the Korean Intellectual Property Office, the disclosure of which is incorporated herein in its entirety by reference.

### BACKGROUND OF THE INVENTION

1. Field of the Invention

The present invention relates to a circuit board where circuit patterns are formed on a top surface and a bottom surface of a substrate, and more particularly, to a circuit board where circuit terminals on the top surface and the bottom surface are interconnected, and to a method of fabricating the same.

2. Description of the Related Art

In a case where many electric devices or semiconductor chips are mounted on a small circuit board, it is advantageous to form two circuit patterns, one on a top surface and the other on a bottom surface of the substrate and connect at least one of the circuit terminals on the top surface to at least one of the circuit terminals of the bottom surface so as to reduce the size of the circuit board.

In a conventional circuit board where circuit terminals on the top surface and the bottom surface are interconnected, such circuit terminals are electrically connected to one another by a conductive filler filled in a through hole formed in the substrate or by a plating layer formed at an inner wall of such a through hole.

FIG. 1A illustrates a circuit board 1 disclosed in U.S. Pat. No. 6,337,037, where an upper terminal 21 and a lower terminal 22 are electrically interconnected by a conductive filler 40 filled in a through hole 35. However, the conductive filler 40 is often filled disconnectedly in the through hole 35, and this causes a failure in connection. In addition, an additional cost for filling the hole of the substrate with the conductive filler 40 may be required.

FIG. 1B illustrates a circuit board 1 disclosed in U.S. Pat. No. 4,622,107, where a conductive plating layer 50, instead of the conductive filler 40, is formed at the inner wall of the through hole 35. However, the conductive plating layer 50 of the circuit board 1 of FIG. 1B has an inferior strength and/or durability under thermal expansion thereof because the conductive plating layer 50 is thin.

### SUMMARY OF THE INVENTION

The present invention provides a circuit board, which is efficient to produce, and has at least an upper terminal and a lower terminal securely interconnected and a method of fabricating the circuit board.

According to an aspect of the present invention, there is provided a circuit board where circuit terminals on the top and bottom surfaces of the substrate are interconnected. The circuit board comprises a substrate having a top surface and a bottom surface and including circuit patterns disposed on the top and bottom surfaces thereof, the substrate defining a connection hole therein; an upper terminal electrically connected to a circuit pattern formed on the top surface of the substrate; and a lower terminal electrically connected to a circuit pattern formed on the bottom surface of the substrate, the lower terminal being located opposite to the upper terminal, wherein the upper terminal and the lower terminal are bonded inside the connection hole of the substrate for electrical connection there-between.

Preferably, end portions of the upper and lower terminals are bonded inside the connection hole. It is also preferable that a conductive plating layer is formed on at least one opposite sides of the ends to facilitate the electrical connection.

According to another aspect of the present invention, there is provided a method of fabricating a circuit board where circuit terminals on the top and bottom surfaces of the substrate are interconnected. The method comprises the steps of: (a) preparing a circuit board which includes a substrate, having a top surface and a bottom surface and including circuit patterns disposed on the top and bottom surfaces thereof, the substrate defining an upper terminal which is electrically connected to a circuit pattern formed on the top surface of the substrate, the substrate further defining a lower terminal which is electrically connected to a circuit pattern formed on the bottom surface of the substrate, the lower terminal being located opposite to the upper terminal; (b) forming at least one connection hole in the substrate adjacent to the upper and lower terminals by etching the substrate; and (c) electrically connecting an end of the upper terminal to an end of the lower terminal inside the connection hole.

It is preferable that the above-identified step (a) further comprises the step of forming a notch adjacent to the ends of the upper and lower terminals, and the step (c) is performed by thermocompression bonding. Preferably, the step (c) further comprises forming a conductive plating layer on at least one opposite surface of the ends of the upper and lower terminals.

According to the present invention, a circuit board which is efficient to produce and has an upper terminal and a lower terminal securely interconnected and a method of fabricating the circuit board are provided.

### BRIEF DESCRIPTION OF THE DRAWINGS

The above and other features and objectives of the present invention will become more apparent by the following embodiments thereof with reference to the attached drawings in which:

FIG. 1A is a sectional perspective view of a conventional circuit board where circuit terminals on a top surface and a bottom surface are interconnected by a conductive filler filled in a through hole;

FIG. 1B is a sectional perspective view of a conventional circuit board where circuit terminals on a top surface and a bottom surface are interconnected by a conductive plating layer formed at an inner wall of a through hole;

FIG. 2 is a sectional perspective view of a circuit board of the invention where circuit terminals on a top surface and a bottom surface are interconnected according to the present invention;

FIG. 3A is a sectional perspective view of a circuit board of the invention having at least one upper terminal on a top surface and one lower terminal on a bottom surface;

FIG. 3B is a cross-sectional view taken along line A-A′ of FIG. 3A;

FIG. 4A is an exploded, partially perspective view showing a portion of a top surface and a bottom surface of a circuit board of the invention where an etching stopper is formed at both surfaces of the circuit board;

FIG. 4B is a cross-sectional view showing a circuit board of the invention in which the top surface and the bottom surface are covered with the etching stopper of FIG. 4A;

FIG. 5 is cross-sectional view showing a circuit board of the invention in which a connection hole is formed therein;

FIG. 6 is a cross-sectional view showing a circuit board of the invention in which the upper terminal and the lower terminal are covered with a plating layer;

FIG. 7 is a cross-sectional view showing a circuit board of the invention from which an etching stopper is removed;

FIG. 8 is a cross-sectional view illustrating a process of connecting an end of an upper terminal to an end of a lower terminal by thermocompression bonding, in accordance with the invention; and

FIG. 9 is a cross-sectional view showing a circuit board whose bonding portions of the upper terminal and the lower terminal are further secured by filling the connection hole with an insulating bonding material.

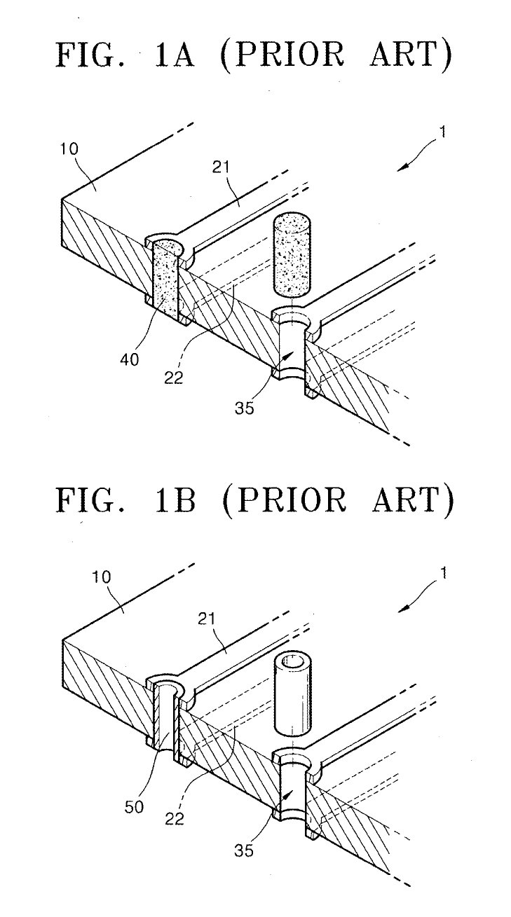

### DETAILED DESCRIPTION OF THE DRAWINGS

The present invention will now be described more fully with reference to the accompanying drawings, in which preferred embodiments of the invention are shown.

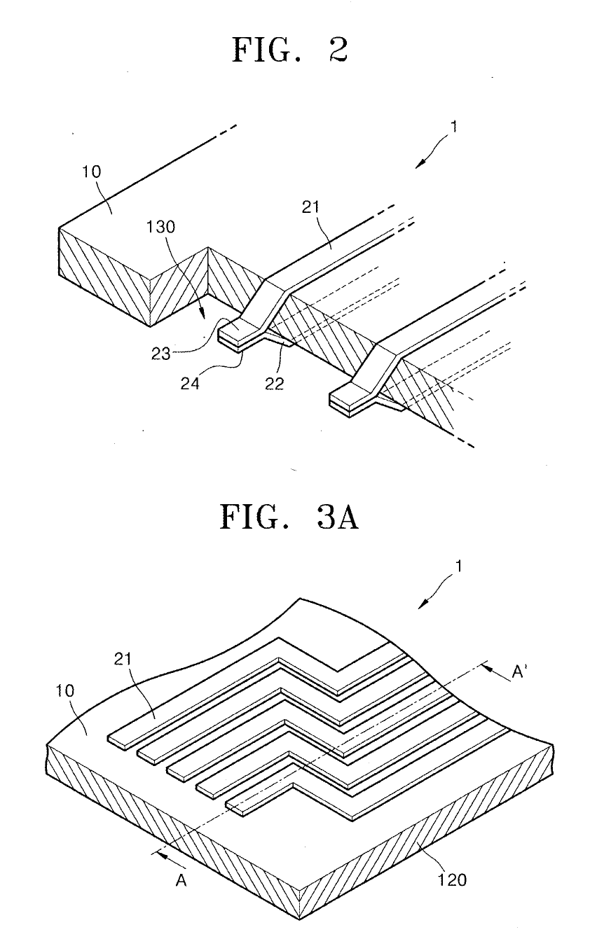

FIG. 2 shows a circuit board I according to the present invention where a circuit pattern (not shown) is formed on a top surface and a bottom surface of a substrate 10. An end 23 of an upper terminal 21 on the top surface of the substrate 10 and an end 24 of a lower terminal 22 on the bottom surface of the substrate 10 are bonded inside a connection hole 130.

The substrate 10 supports two circuit patterns formed respectively on the top surface and the bottom surface, and insulates the circuit patterns.

The upper terminal 21 and the lower terminal 22 each may be a part of the circuit pattern respectively formed at the top surface and the bottom surface or a separate element which is electrically connected to the circuit pattern. The upper terminal 21 and the lower terminal 22 are connected preferably in an orthogonal direction to the circuit board 1.

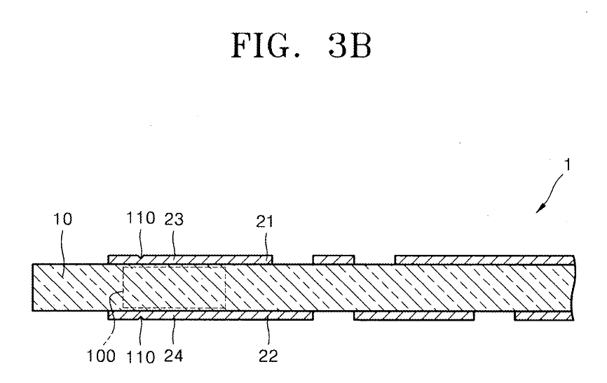

The connection hole 130 is used to connect the end 23 of the upper terminal 21 to the end 24 of the lower terminal 22. It is preferable that the size of the connection hole 130 is as small as possible, but large enough to provide a space in which the upper terminal 21 and the lower terminal 22 can be firmly connected. The connection hole 130 can be formed, for example, by etching a connection area 100 shown in FIG. 3B where the end 23 of the upper terminal 21 and the end 24 of the lower terminal 22 are interconnected therein, or by forming the substrate 10 with the connection area 100 empty, or by blanking the substrate 10. If the connection hole 130 is formed by a method other than etching the upper terminal 21 and the lower terminal 22 have to be configured to support the ends 23 and 24 over the connection hole 130. In addition, it is preferable that the end 23 of the upper terminal 21 and the end 24 of the lower terminal 22 are arranged in a predetermined area of the circuit board 1 so as to minimize the number of the connection hole 130.

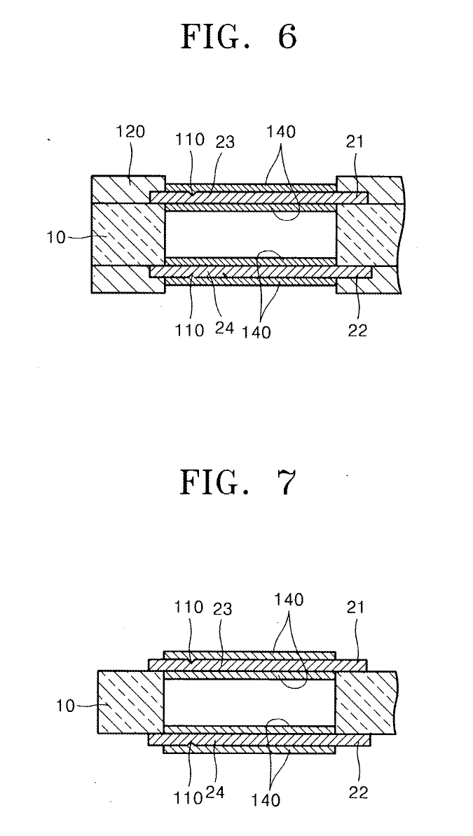

On the other hand, the end 23 of the upper terminal 21 and the end 24 of the lower terminal 22 can be bonded by thermocompression bonding, resistance welding, or any other conceivable methods of bonding metals. In the present disclosure, a bonding method performed particularly by using thermocompression bonding is described. In this case, it is preferable that conductive plating layers 140 as shown in FIG. 6 are formed respectively on at least one opposite side of the ends 23 and 24 to facilitate and secure the thermocompression bonding. The conductive plating layers 140 may be formed of a metal such as gold, tin, or the like.

In addition, after the end 23 of the upper terminal 21 and the end 24 of the lower terminal 24 are bonded together, the connected portion of the ends 23 and 24 are preferably covered with an insulating substance to protect or prevent separation of the ends 23 and 24, which may be caused by an unintended contact by foreign objects.

Hereinafter, a method of fabricating the circuit board is described.

The circuit board can be prepared by a conventional method. For example, a metal layer is first formed on a top surface and a bottom surface of a substrate and photoresist is coated on its insulating portion. Then, a series of exposure, development, etching, and exfoliation processes are performed to provide circuit patterns on the top surface and the bottom surface of the substrate.

FIGS. 3A and 3B show a circuit board 1 where an upper terminal 21 is formed on a top surface of the substrate 10 and a lower terminal 22 is formed on a bottom surface of the substrate 10. The upper terminal 21 and the lower terminal 22 may be a part of circuit patterns on the top and bottom surfaces or separate elements which are electrically connected to the circuit patterns. Whether the upper terminal 21 and the lower terminal 22 are to be a part of the circuit patterns or separate elements can be determined based on characteristics of the circuit board, integrity of the circuit, and/or characteristics of the materials constituting the circuit patterns, etc.

After the circuit board 1 is prepared, a connection hole 130 is formed in the substrate 10, particularly, in an area 100 between the end 23 of the upper terminal 21 and the end 24 of the lower terminal 22. Location and size of the connection hole 130 are determined based on the locations of circuit elements mounted on the circuit board 1 and materials constituting the substrate 10. The shape of the connection hole 130 is not limited to a straight volumn as shown in FIG. 3B, and it may be formed along any curvature or as a diagram such as a polygon or a circle.

The connection hole 130 functions as a path connecting the top surface of the substrate 10 with the bottom surface of the substrate 10. Thus, the location of the connection hole 130 is not necessarily limited to the outer circumference (i.e., edges) of the substrate 10. In other words, the connection hole 130 may be formed either at an intermediate or inner portion of the substrate 10 or at an outer circumference of the substrate 10. If the connection hole 130 is formed at an intermediate portion of the substrate 10, the circumference of the connection hole 130 is enclosed by the substrate 10. However, if the connection hole 130 is formed at the outer circumference of the substrate 10, at least one side of the connection hole 130 is open from the side of the substrate 10.

The location of the connection hole 130 is further related to the location and/or arrangement of elements mounted on the substrate 10, such as semiconductor chips and connection terminals arranged thereon. For example, if the semiconductor chip is mounted at an intermediate area of the substrate 10 and the connection terminal is disposed under the semiconductor chip, it is preferable that the connection hole 130 is formed under the semiconductor chip. In contrast, if the connection terminal is formed around the semiconductor chip, it is preferable that the circuit pattern, connected with the connection terminal, is formed in the circumference of the substrate 10 and the connection hole 130 is formed in the circumference of the substrate 10.

Meanwhile, if there are a plurality of upper terminals and lower terminals that must be connected with one another, it is preferable that the upper and lower terminals are connected through the least possible number of connection holes so as to reduce the size of the circuit board.

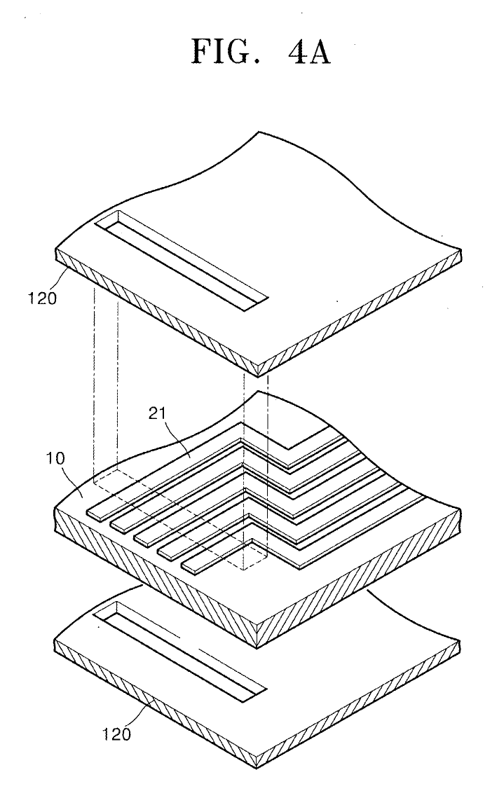

In order to form the connection hole 130 by etching, an etching stopper 120 is disposed on the top and bottom surfaces of the substrate 10 except the area 100 where the connection hole 130 is to be formed as shown in FIGS. 4A and 4B. After the etching stopper 120 is disposed, the connection hole 130 is formed by applying an etching solution to the area 100 where the connection hole 130 is to be formed. Thereby, etching starts from the surface of the circuit board 1 where the etching stopper 120 and a terminal are not formed at the substrate 10 and proceeds inwards the substrate between the end 23 of the upper terminal 21 and the end 24 of the lower terminal 22. After the connection hole 130 is formed, the etching solution is cleaned or removed from the circuit board 1. The upper terminal 21 and the lower terminal 22 are composed of materials that are not to be etched by the etching solution.

After the connection hole 130 is formed, the circuit board 1 has a cross-section as shown in FIG. 5. Then, the upper terminal 21 and the lower terminal 22 are electrically connected inside the connection hole 130.

The upper terminal 21 and the lower terminal 22 can be connected by first cutting the ends 23 and 24 of the upper and lower terminals 21 and 22 (adjacent to notch 110), there-after bending or drawing the upper terminal 21 and the lower terminal 22 to join inside the connection hole 130 of the circuit board 1, and bonding the ends 23 and 24 of the upper and lower terminals 21 and 22 together. The upper terminal 21 and the lower terminal 22 can alternatively be connected by directly bending or drawing the upper terminal 21 and the lower terminal 22 inwards to join inside the connection hole 130 and then bonding them together, without first cutting their ends 23 and 24, if the substrate 10 is thin and the upper and lower terminals 21 and 22 are sufficiently malleable.

With reference to FIG. 2, if the ends 23 and 24 of the upper and lower terminals 21 and 22 are cut, a total of four ends are respectively formed in the left and right sides of the connection hole 130 (two on the top and two on the bottom of the substrate 10). In this case, it is not necessary to bond the right end 23 of the upper terminal 21 and the right end 24 of the lower terminal 22 as shown in FIG. 2. It is possible to bond the left side end of the upper terminal 21 and right side end of the lower terminal 22. However, if the ends of the upper and lower terminals of the same side are bonded, it is possible to bond the other sides together as shown in the drawing figure. In that case, it is advantageous in that multiple ends of upper terminals and lower terminals can be bonded within one connection hole.

The end 23 of the upper terminal 21 and the end 24 of the lower terminal 22 can be cut by an additional cutting process. However, they can be cut at the same time when thermocompression bonding (to be described herein-after) is performed if a notch 110 is formed adjacent to the end 23 of the upper terminal 21 and the end 24 of the lower terminal 22 to facilitate cutting during compression by the bonding device. The notch 110 can be formed easily before the connection hole 130 is formed in the circuit board. Alternatively, the notch 110 may be formed after the connection hole 130 is formed.

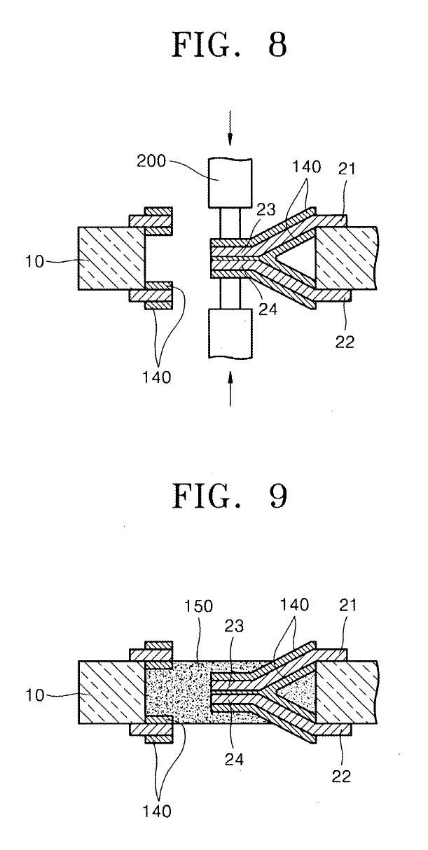

The upper terminal 21 and the lower terminal 22 can be bonded by a method of metal bonding known in the art. If the upper terminal 21 and the lower terminal 22 are bonded by thermocompression bonding, it is preferable that a conductive plating layer 140 usable for thermocompression bonding is formed on at least one opposite surface of the ends 23 and 24. It is preferable that the conductive plating layer 140 is formed in an area where the end 23 of the upper terminal 21 and the end 24 of the lower terminal 22 are to be bonded before the etching stoppers 120 are removed, as shown in FIG. 6. After the conductive plating layer 140 is formed, thermocompression bonding is performed by using a thermocompression bonding device 200 as shown in FIG. 8. However, it is possible to remove the etching stopper before or after performing thermocompression bonding.

If the circuit board 1 is used with the open connection hole 130 as described above, a bonding portion of the upper terminal 21 and the lower terminal 22 may be separated by unintended contact by foreign objects. In order to prevent the terminals 21 and 22 from being separated from each other, it is preferable that a connected portion of the end 23 of the upper terminal 21 and the end 24 of the lower terminal 22 is covered with an insulating adhesive substance 150 as shown in FIG. 9.

Since the end 23 of the upper terminal 21 and the end 24 of the lower terminal 22 are bonded inside the connection hole 130 of the circuit board, the circuit board can be compacted and effectively manufactured, and the bonding portion of the upper terminal and the lower terminal has a superior strength and durability.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A circuit board comprising:
a substrate having a top surface and a bottom surface and including circuit patterns disposed on the top and bottom surfaces thereof, the substrate defining a connection hole therein;
an upper terminal electrically connected to a circuit pattern formed on the top surface of the substrate; and
a lower terminal electrically connected to a circuit pattern formed on the bottom surface of the substrate, the lower terminal being located opposite to the upper terminal,
wherein the upper terminal and the lower terminal are bonded inside the connection hole of the substrate for electrical connection there-between.

2. The circuit board of claim 1, wherein an end portion of the upper terminal and an end portion of the lower terminal are bonded inside the connection hole.

3. The circuit board of claim 1, wherein an intermediate portion of the upper terminal and an intermediate portion of the lower terminal are bonded inside the connection hole.

4. The circuit board of claim 1, wherein a conductive plating layer is disposed on at least one opposite side of the terminals for facilitating the electrical connection.

5. The circuit board of claim 1, wherein the connection hole is formed at an intermediate portion of the substrate.

6. The circuit board of claim 1, wherein the connection hole is formed at an outer circumference of the substrate.

7. The circuit board of claim 1, wherein the connection hole is formed by etching.

8. The circuit board of claim 1, wherein the substrate defines a single connection hole.

9. The circuit board of claim 8, wherein a pair of upper and lower terminals are bonded inside the single connection hole.

10. The circuit board of claim 8, wherein plural pairs of upper and lower terminals are bonded inside the single connection hole.

11. The circuit board of claim 1, wherein the substrate defines a plurality of connection holes.

12. The circuit board of claim 11, wherein plural pairs of upper and lower terminals are bonded inside the connection holes.

13. The circuit board of claim 1, wherein the connection hole is filled with an insulating material to at least partially enclose the terminals bonded therein.

14. A method of fabricating a circuit board comprising the steps of:
(a) preparing a circuit board which includes a substrate, having a top surface and a bottom surface and including circuit patterns disposed on the top and bottom surfaces thereof, the substrate defining an upper terminal which is electrically connected to a circuit pattern formed on the top surface of the substrate, the substrate further defining a lower terminal which is electrically connected to a circuit pattern formed on the bottom surface of the substrate, the lower terminal being located opposite to the upper terminal;
(b) forming at least one connection hole in the substrate adjacent to the upper and lower terminals by etching the substrate; and
(c) electrically connecting an end of the upper terminal to an end of the lower terminal inside the connection hole.

15. The circuit board of claim 14, wherein the step (c) is performed by thermocompression bonding.

16. The method of claim 14, wherein the step (a) further includes the step of forming a notch adjacent to the ends of the upper and lower terminals which will be cut during the thermocompression bonding.

17. The method of claim 16, wherein the step (c) is performed by thermocompression bonding.

18. The method of claim 17, wherein the step (c) further includes forming a conductive plating layer on at least one opposite surface of the ends of the upper and lower terminals for facilitating the thermocompression bonding.
